(19) United States
(12) Patent Application Publication
(10) Pub. No.: US 2006/0081891 A1
(43) Pub. Date: Apr. 20, 2006

(54) Nonvolatile semiconductor memory capable of storing data of two bits or more per cell

(75) Inventor: Kenichirou Nakagawa, Kanagawa (JP)

Correspondence Address: FOLEY AND LARDNER LLP;SUITE 500, 3000 K STREET NW, WASHINGTON, DC, 20007, US

(73) Assignee: NEC Electronics Corporation

(21) Appl. No.: 11/252,619

(22) Filed: Oct. 19, 2005

(30) Foreign Application Priority Data
Oct. 20, 2004 (JP) 2004-305288

(51) Int. Cl. H01L 29/80

(52) U.S. Cl. 257/261

(57) ABSTRACT

A nonvolatile semiconductor memory includes a gate insulating layer, a control gate layer, a first silicide layer, charge accumulating layers, memory gate layers and second silicide layers. The gate insulating layer is formed on a first region of a semiconductor substrate. The control gate layer is formed on the gate insulating layer. The first silicide layer is formed on the control gate layer. The charge accumulating layer is formed on one side of the first region of the semiconductor substrate, and capable to accumulate charges. The memory gate layers is formed on the charge accumulating layer, away from the control gate layer. The second silicide layer is formed on the memory gate layer. The memory gate layer includes a thick gate layer and a thin gate layer. The thick gate layer is formed far side from the control gate layer, and bonded to the second silicide layer. The thin gate layer is formed near side from the control gate layer, thinner in a layer thickness than the thick gate layer and shorter in a height than the control gate layer.

### BACKGROUND OF THE INVENTION

1. Field of the Invention

The present invention relates to a nonvolatile semiconductor memory. More specifically, the present invention relates to a nonvolatile semiconductor memory capable of storing data of two bits or more per cell.

2. Description of the Related Art

Recently, with a view of highly integrating a nonvolatile semiconductor memory (hereinafter, also referred to as “nonvolatile memory”), a nonvolatile memory capable of storing two-bit data in one cell has been developed. For example, Tomoko Ogura et al., “Embedded Twin MONOS Flash Memories with 4 ns and 15 ns Fast Access Times”, 2003 Symposium on VLSI Circuits Digest of Technical Papers, PP. 207-210 (hereinafter referred to as a “reference 1”) discloses a conventional nonvolatile memory. FIG. 1 is a cross-sectional view showing the conventional nonvolatile memory disclosed in the reference 1. As shown in FIG. 1, the nonvolatile memory includes memory cells 102 formed on a surface of a silicon substrate 101.

In each memory cell 102, source and drain regions 106 are formed on the surface of the silicon substrate 101. A gate insulating film 103 is provided on a region right on a region between the source and drain regions 106 on the surface of the silicon substrate 101. A control gate 104 serving as a word line is provided on the gate insulating film 103. A silicide 105 is formed on an upper surface of the control gate 104. Memory gates 108 are provided on both sides of the control gate 104, respectively. An oxide-nitride-oxide (ONO) film 107 is provided between the control gate 104 and the memory gate 108 and between the memory gate 108 and the silicon substrate 101. The source and drain regions 106 are connected to a bit line 110 on an upper layer (see FIG. 2) through a contact (not shown).

By selecting a charged state of a nitride film in the ONO film 107, i.e., selecting whether to accumulate electrons in this nitride film, the nonvolatile memory configured as stated above can store binary data. By controlling charged states of the ONO films 107 on the both sides of the control gate 104 independently of each other, two-bit data can be stored in one memory cell 102. It is noted that the memory gates 108 are provided to facilitate injecting and emitting electrons into and from the nitride film of the ONO film 107 and to facilitate reading the data.

Operations of the conventional nonvolatile memory shown in FIG. 1 will be described. A data write operation will first be described. A positive potential of about 0.8 V is applied to the control gate 104. A positive potential of about 5.5 V is applied to the write-side (hereinafter, “selected-side”) memory gate 108. A positive potential of about 3.3 V is applied to the non-write-side (hereinafter, “unselected-side”) memory gate 108 paired with the selected-side memory gate 108. A positive potential of about 4.5 V is applied to the selected-side source and drain region 106. By doing so, hot electrons generated in a channel region are injected into the nitride film in the selected-side ONO film 107. This injection is referred to as the “channel hot electron” (CHE) injection. The CHE injection enables data to be written to the memory cell 102.

A written data erasure operation will be described. A negative potential of about −1 V is applied to the control gate 104. A negative potential of about −3 V is applied to the selected-side memory gate 108. A positive potential of about 3.3 V is applied to the unselected-side memory gate 108. A positive potential of about 4 V is applied to the selected-side source and drain region 106. By doing so, hole-electron pairs are generated by an interband tunnel, the holes or holes generated by collision of the holes are accelerated and transformed into hot holes, and the hot holes are injected into the nitride film of the selected-side ONO film 107. As a result, negative charges accumulated in the nitride film of ONO film 107 are cancelled and data is erased.

A written data read operation will be described. A positive potential of about 1.8 V is applied to the control gate 104. A positive potential of about 1.8 V is applied to the selected-side memory gate 108. A positive potential of about 3.3 V is applied to the unselected-side memory gate 108. A positive potential of about 1.8 V is applied to the unselected-side source and drain region 106. In this state, a threshold of the memory cell 102 is detected. If negative charges are accumulated in the selected-side ONO film 107, the threshold is higher than the threshold if no negative charges are accumulated therein. By detecting the threshold, the data written to the selected-side ONO film 107 can be read. At this time, even if the negative charges are accumulated in the unselected-side ONO film 107, it is possible to suppress influence of the negative charges accumulated in the unselected-side ONO film 107 and detect a charged state of the selected-side ONO film 107 by applying a positive potential of about 0.3.3 volts to the unselected-side memory gate 108 and applying a positive potential of about 1.8 volts to the unselected-side source and drain region 106. In this way, two-bit data is recorded in each cell in the conventional nonvolatile memory shown in FIG. 1.

However, the conventional technique described above has the following disadvantages. As shown in FIG. 1, in this conventional nonvolatile memory, each memory gate 108 is narrow and contains only of polysilicon, and a surface of the memory gate 108 is not silicided. Due to this, the memory gate 108 has a high resistance. FIG. 2 is a plan view showing the conventional nonvolatile memory shown in FIG. 1. (Note that the ONO films 107 and the silicide film 105 (see FIG. 1) are not shown.) As shown in FIG. 2, since the memory gate 108 is narrow and the surface thereof is not silicided, the memory gate 108 has a high resistance. Due to this, if the memory gate 108 is to be used solely, it takes lots of time to charge the memory gate 108 during write, erasure, and read operations.

To avoid this disadvantage, i.e., to reduce the resistance of the memory gate 108, a back wiring extending in parallel to the memory gate 108 is formed on an upper wiring layer, and connected to the memory gate 108 in the conventional nonvolatile memory.

For example, a contact formation region 113 is provided for every 16 bit lines 110 to extend in the same direction as an extension direction of the bit lines 110. In this contact formation region 113, extension sections 108a mutually connecting the memory gates 108 are provided. Each extension section 108a extends from one memory gate 108 in a direction orthogonal to an extension direction of the memory gate 108, and is connected to another memory gate 108 opposite to this memory gate 108 across the source and drain regions 106. A contact (not shown) is provided on this extension section 108a. A wiring 109 is provided on the same wiring layer as that on which the bit line 110 is provided. A via hole 111 is provided on this wiring 109. A wiring 112 extending in the same direction as the extension direction of the memory gate 108 is provided on an upper layer than the layer on which the bit line 110 is provided. By so configuring, the wiring 112 is connected to the memory gate 108 through the via hole 111, the wiring 109, the contact (not shown), and the extension section 108a, and thus serves as the back wiring of the memory gate 108.

As can be seen, in this conventional nonvolatile memory, by providing the back wiring for the memory gate 108, the back wiring compensates for a height of the resistance of the memory gate 108 itself to thereby prevent deceleration of an operating rate. However, as stated above, the contact formation regions 113 cannot exhibit a sufficient effect if they are not arranged somewhat at a high density, for example, one contact formation region 113 for every 16 bit lines. This disadvantageously makes the nonvolatile memory large in macro size.

Further, an upper portion of the memory gate 108 may be silicided so as to reduce the resistance of the memory gate 108. However, as can be seen from FIG. 1, the upper portion of the memory gate 108 and an end of the silicide 105 are located quite close to each other. Due to this, the following disadvantage occurs. If the upper portion of the memory gate 108 is to be silicided, then a silicide of the upper portion-side memory gate 108 extends toward the silicide 105 while rising over the insulating film and is electrically connected to the end of the silicide 105, or conversely, the end of the silicide 105 extends toward the memory gate 108 and is electrically connected to the silicide of the upper portion-side memory gate 108.

### SUMMARY OF THE INVENTION

It is, therefore, an object of the present invention to provide a nonvolatile semiconductor memory capable of operating at high rate while suppressing a macro size to be small and a method for manufacturing the same.

In order to achieve an aspect of the present invention, the present invention provides a nonvolatile semiconductor memory including: a gate insulating layer which is formed on a first region of a semiconductor substrate; a control gate layer which is formed on said gate insulating layer; a first silicide layer which is formed on said control gate layer; charge accumulating layers, each of which is formed on one of both sides of said first region of said semiconductor substrate, and capable to accumulate charges; memory gate layers, each of which is formed on one of said charge accumulating layers, away from said control gate layer; and second silicide layers, each of which is formed on one of said memory gate layers, wherein said one of the memory gate layers includes: a thick gate layer which is formed far side from said control gate layer, and bonded to one of said second silicide layers, and a thin gate layer which is formed near side from said control gate layer, thinner in a layer thickness than said thick gate layer and shorter in a height than said control gate layer.

In the present invention, the second silicide with low resistance is provided on the memory gate layer. Therefore, it is unnecessary to provide the back wiring, and the contact formation region. Namely, the macro size of the nonvolatile semiconductor memory can be made small and the nonvolatile semiconductor memory can operate at high rate. In addition, the effective distance between the first and second silicides can be made large by providing a thin gate layer. Therefore, the electrical connection between the first and second silicides can be prevented. Besides, because of the large effective distance, even if a manufacturing fluctuation somewhat occurs, such a failure as the electrical contact between the silicides hardly occurs. The nonvolatile semiconductor memory can be, therefore, manufactured at higher yield.

### BRIEF DESCRIPTION OF THE DRAWINGS

The above and other objects, advantages and features of the present invention will be more apparent from the following description taken in conjunction with the accompanying drawings, in which:

FIG. 1 is a cross-sectional view showing a conventional nonvolatile memory;

FIG. 2 is a plan view showing the conventional nonvolatile memory shown in FIG. 1;

FIG. 3 is a cross-sectional view showing a configuration of a nonvolatile semiconductor memory according to an embodiment of the present invention;

FIG. 4 is a plan view showing the configuration of the nonvolatile semiconductor memory according to the embodiment of the present invention; and

FIGS. 5A to 5D, to 18A to 18D are cross-sectional views showing a part of a method for manufacturing the nonvolatile semiconductor memory according to the embodiment of the present invention.

### DESCRIPTION OF THE PREFERRED EMBODIMENTS

Embodiments of a nonvolatile semiconductor memory and a method for manufacturing a nonvolatile semiconductor memory according to the present invention will be described below with reference to the attached drawings.

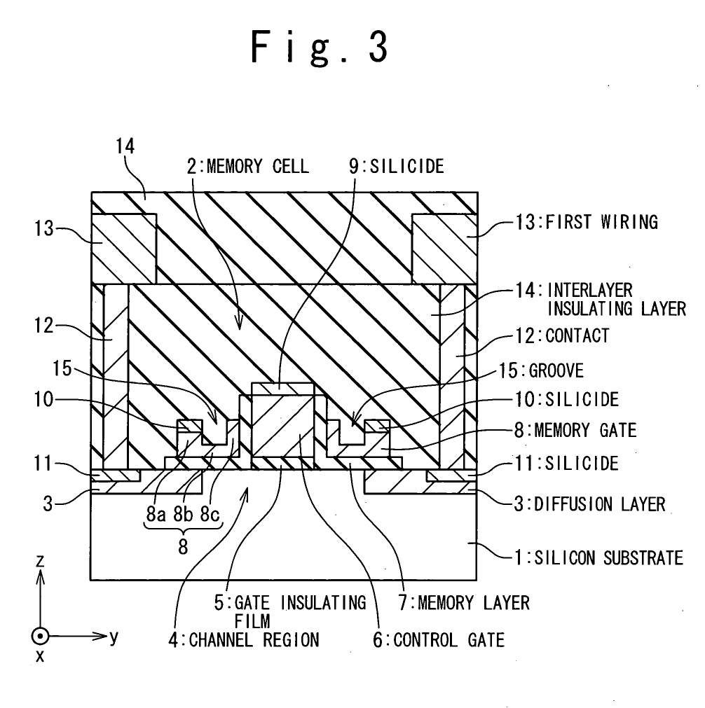

A configuration of the nonvolatile semiconductor memory according to an embodiment of the present invention will first be described. FIG. 3 is a cross-sectional view showing a configuration of a nonvolatile semiconductor memory according to an embodiment of the present invention. The nonvolatile semiconductor memory includes memory cells 2, contacts 12, first wirings 13, and interlayer insulating layers 14.

Each memory cell 2, which is provided on a silicon substrate 1, can store two-bit data. The memory cell 2 includes a diffusion layer 3, a gate insulating film 5, a control gate 6, a memory layer 7, a memory gate 8, and silicides 9, 10, and 11.

The gate insulating film 5 is provided on a predetermined first region of the silicon substrate 1 (a central portion of a channel region 4). The gate insulating film 5 contains, for example, silicon oxide. The control gate 6 is provided on the gate insulating film 5. The control gate 6 contains, for example, polysilicon at a width of 50 nm. The silicide 9 is provided on the control gate 6 and contains, for example, cobalt silicide.

The memory layers 7 (charge accumulation layers) are provided on both side surfaces (right and left sides in FIG. 3) of the gate insulating film 5 and the control gate 6, and on both sides (right and left sides in FIG. 3) of a first region of the silicon substrate 1, respectively. Each memory layer 7 can accumulate charges. The memory layer 7 has a multilayered structure in which, for example, an silicon oxide film, an insulating film higher in dielectric constant than a silicon oxide film and a silicon oxide film are provided in this order. With this structure, charges are accumulated in the insulating film higher in dielectric constant than the silicon oxide film. Examples of the insulating film higher in dielectric constant than the silicon oxide film include a silicon nitride film. Namely, the memory layer 7 having the multilayered structure is, for example a silicon oxide-nitride-oxide (ONO) film. Alternatively, the memory layer 7 may have a structure in which a plurality of conductive particles (quantum dots) are dispersed in an insulating film. Examples of the quantum dot structure include a structure in which a silicon oxide film, silicon particles, and a silicon oxide film are provided in this order. With this structure, charges are accumulated in the silicon particles.

The memory gate 8 is provided on the memory layer 7 to be electrically isolated from the control gate 6. The memory gate 8 includes a thick film gate 8a, a thin film gate 8b, and a boundary gate 8c.

The thick film gate 8a is provided far from the control gate 6 and an upper portion of the thick film gate 8a is bonded to the silicide 10 (e.g., cobalt silicide). The thick film gate 8a is thicker than the thin film gate 8b. A thickness of the thick film gate 8a is preferably larger than 30 nm and equal to or smaller than 300 nm. By so setting, the thick film gate 8a can be made thicker than the thin film gate 8b. A height of the thick film gate 8a from the surface of the silicon substrate is preferably smaller than that of the control gate 6 from the surface of the silicon substrate 1. By so setting, a large distance can be secured between the silicides 9 and 10, which can prevent the silicides 9 and 10 from being electrically connected to each other.

The thin film gate 8b is provided closer to the control gate 6 than the thick film gate 8a. The thin film gate 8b is thinner than the thick film gate 8a. A height of the thin film gate 8b from the surface of the silicon substrate 1 is preferably smaller than that of the control gate 6 from the surface of the silicon substrate 1. A height of the thin film gate 8b from the surface of the silicon substrate 1 (on the side surface of the control gate 6) is preferably smaller than that of the memory layer 7 from the surface of the silicon substrate 1. By so setting, the thin film gate 8b can be covered with an insulating film 37 (to be described later) during silicide formation, a sufficient length can be secured between an exposed surface of the control gate 6 and that of the memory gate 8, and the electrical connection between the silicides 9 and 10 can be prevented. As setting a thickness of the thin film gate 8b to be equal to or larger than 10 nm, the memory gate 8 can normally function as a memory gate.

The boundary gate 8c is provided closer to the control gate 6 than the thin film gate 8b. The boundary gate 8c is in contact with the memory layer 7 on the side surface of the control gate 6. A height of the boundary gate 8c from the surface of the silicon substrate 1 (on the side surface of the control gate 6) is preferably smaller than that of the memory layer 7 from the surface of the silicon substrate 1. A width of the boundary gate 8c is preferably equal to or smaller than 30 nm. Since the boundary gate 8c is set to be small in both height and width, a surface of the boundary gate 8b can be sufficiently covered with the insulating film 37 during silicide formation even if the boundary gate 8c is thicker than the thin film gate 8b. In addition, a sufficiently large distance can be secured between the exposed surface of the control gate 6 and that of the memory gate 8, and the electrical connection between the silicides 9 and 10 can be prevented.

A lower limit of the thickness of the thin film gate 8b, an upper limit of the width of the boundary gate 8c, and a thickness of a polysilicon film 26 (to be described later) are preferably equal to or larger than 10 nm and equal to or smaller than 30 nm.

The thick film gate 8a, the thin film gate 8b, and the boundary gate 8c are generally U-shaped as a whole. It is assumed herein that the thick film gate 8a is a layer corresponding to one longitudinal part of the U shape, that the thin film gate 8b is a layer corresponding to a bottom of the U shape, and that the boundary gate 8c is a layer corresponding to the other longitudinal part of the U shape. The thick film gate 8a, the thin film gate 8b, and the boundary gate 8c form a groove 15 between the silicides 9 and 10. By forming this groove 15, if the silicide 10 is grown along the thin film gate 8b, then a path to the silicide 9 can be made sufficiently long, and the electrical connection between the silicides 9 and 10 can be prevented. Alternatively, the thick film gate 8a, the thin film gate 8b, and the boundary gate 8c may be generally J-shaped as a whole. In this case, the boundary gate 8c is slightly small in height. In this case, similarly to the former case, a sufficiently long distance can be secured between the thick film gate 8a and the silicide 9, so that a sufficiently long path from the silicide 10 to the silicide 9 can be secured.

The diffusion layer 3 is embedded in the surface of the silicon substrate 1. The diffusion layer 3 functions as a source or a drain. The diffusion layer 3 is embedded in a region below the silicide 10 in the surface of the silicon substrate 1. A region including the first region below the gate insulating film 5 between the diffusion layers 3 is the channel region 4. Each diffusion layer 3 is connected to the memory layer 7 and also connected to a first wiring 13 through the silicide 11 (e.g., cobalt silicide) and the contact 12. The respective constituent elements are buried in the interlayer insulating film 14.

Each diffusion layer 3 preferably extends to the region below the silicide 10, because the distance between the two diffusion layers 3 (the length of the channel region 4) can be made small and an electrical resistance of the channel region can be reduced. It is thereby possible to improve characteristics of the memory cell 2 such as an operating rate.

To enable the memory cell 2 to store data, it is necessary to secure a region of the memory layer 7, which region can accumulate charges (a region of the memory layer 7 from an end of the diffusion layer 3 to the side surface of the control gate 6). For this reason, a lower limit of the distance between the two diffusion layers 3 is determined in a design phase.

According to the present invention, the effective distance between the suicides 9 and 10 can be made large, so that the electrical connection between the silicides 9 and 10 can be prevented. Besides, because of the large effective distance, even if a manufacturing fluctuation somewhat occurs, such a failure as the electrical contact between the silicides hardly occurs. The nonvolatile semiconductor memory can be, therefore, manufactured at high yield.

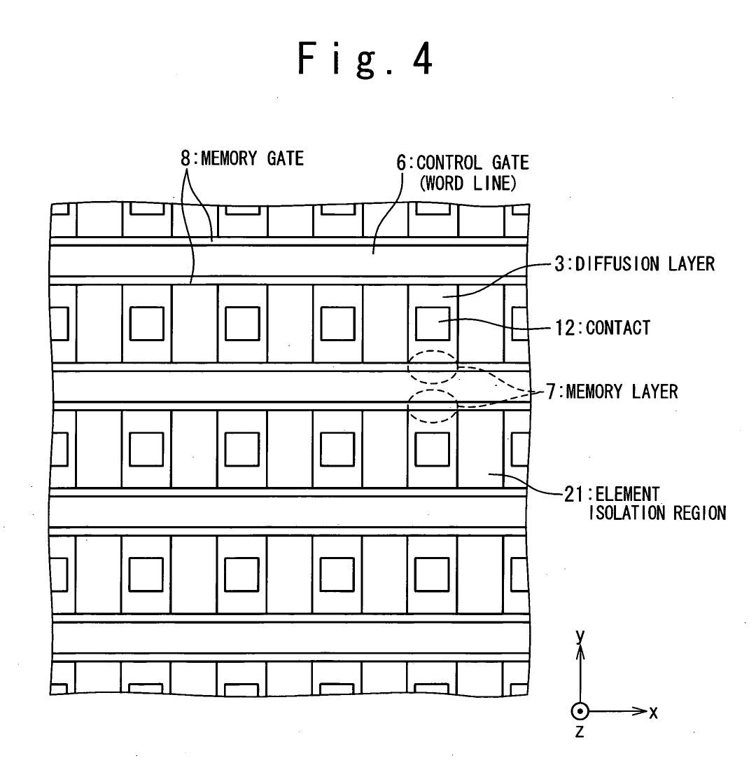

FIG. 4 is a plan view showing the configuration of the nonvolatile semiconductor memory according to the embodiment of the present invention. In FIG. 4, structures above the first wiring 13 and the silicides 9 and 10 are not shown.

On silicon substrate 1, a plurality of control gates 6 serving as word lines are provided in a first direction (an X direction in FIG. 4) in parallel. Memory gates 8 extending in the first direction (X direction) similarly to the control gates 6 are provided on both sides of the control gates 6. One control gate 6 and two memory gates 8 on both sides of the control gate 6, respectively, constitute one gate group.

Element isolation regions 21 and the diffusion layers 3 are alternately formed on the surface of the silicon substrate 1 below and between the gate groups along the first direction (X direction) in which the control gates 6 extend. A plurality of bit lines (not shown) extending in a second direction (a Y direction in FIG. 4) orthogonal to the first direction are provided on a wiring layer above the layer on which the memory cells 2 are provided. The contact 12 is connected to the adjacent contact 12 by a wiring (not shown) to form a pair. The wiring is connected to the bit line (not shown) by the via hole. The memory cell 2 (including the control gate 6 as well as the memory gates 8 and the memory layers 7 on both sides of the control gate 6) is formed per most proximate contact between a region between the bit lines and the gate group. That is, the memory cell 2 is formed per intersecting point between the region between the bit lines and the gate group if viewed from a direction perpendicular to the surface of the silicon substrate 1. Thus, a plurality of memory cells 2 are arranged in a matrix in the nonvolatile semiconductor memory. FIG. 3 is a cross-sectional view orthogonal to the first direction (X direction).

According to the present invention, the low resistance silicide 10 is provided on the memory gate 8. Therefore, it is unnecessary to provide the back wiring, the contact formation region, and the like differently from the conventional technique. Namely, the macro size of the nonvolatile semiconductor memory can be made small and the nonvolatile semiconductor memory can operate at high rate.

Referring to FIG. 3, operations performed by the nonvolatile semiconductor memory according to this embodiment will next be described below. A data write operation will first be described. A positive potential of about 1.0 V is applied to the control gate 6. A positive potential of about 5 V is applied to the write-side (hereinafter, “selected-side”) memory gate 8. A positive potential of about 3 V is applied to the non-write-side (hereinafter, “unselected-side”) memory gate 8 paired with the selected-side memory gate 8, and a positive potential of about 5 V is applied to the selected-side diffusion layer 3. By doing so, hot electrons generated in the channel region 4 are injected into the nitride film of the selected-side memory layer 7. This injection is referred to as “channel hot electron (CHE)” injection. The CHE injection enables data to be written to the memory cell 2.

A written data erasure operation will be described. A negative potential of about −1 V is applied to the control gate 6. A negative potential of about −5 V is applied to the selected-side memory gate 8, a positive potential of about 3 V is applied to the unselected-side memory gate 8, and a positive potential of about 5 volts is applied to the selected-side diffusion layer 3. By doing so, hole-electron pairs are generated by an interband tunnel, the holes or holes generated by collision of the holes are accelerated and transformed into hot holes, and the hot holes are injected into the nitride film of the selected-side memory layer 7. As a result, negative charges accumulated in the nitride film of the memory layer 7 are cancelled and data is thereby erased.

A written data read operation will be described. A positive potential of about 1.8 V is applied to the control gate 6, a positive potential of about 1.8 V is applied to the selected-side memory gate 8, a positive potential of about 3.3 V is applied to the unselected-side memory gate 8, and a positive potential of about 1.5 V is applied to the unselected-side diffusion layer 3. In this state, a threshold of the memory cell 2 is detected. If negative charges are accumulated in the selected-side memory layer 7, the threshold is higher than the threshold if no negative charges are accumulated therein. By detecting the threshold, the data written to the unselected-side memory layer 7 can be read. At this time, even if the negative charges are accumulated in the unselected-side memory layer 7, it is possible to suppress influence of the negative charges accumulated in the unselected-side memory layer 7 and detect a charged state of the selected-side memory layer 7 by applying a positive potential of about 3.3 V to the unselected-side memory gate 8 and applying a positive potential of about 1.5 V to the unselected-side diffusion layer 3. Thus, two-bit data is recorded in each memory cell 2 shown in FIG. 3.

A method for manufacturing a nonvolatile semiconductor memory according to the embodiment of the present invention will be described below with reference to attached drawings.

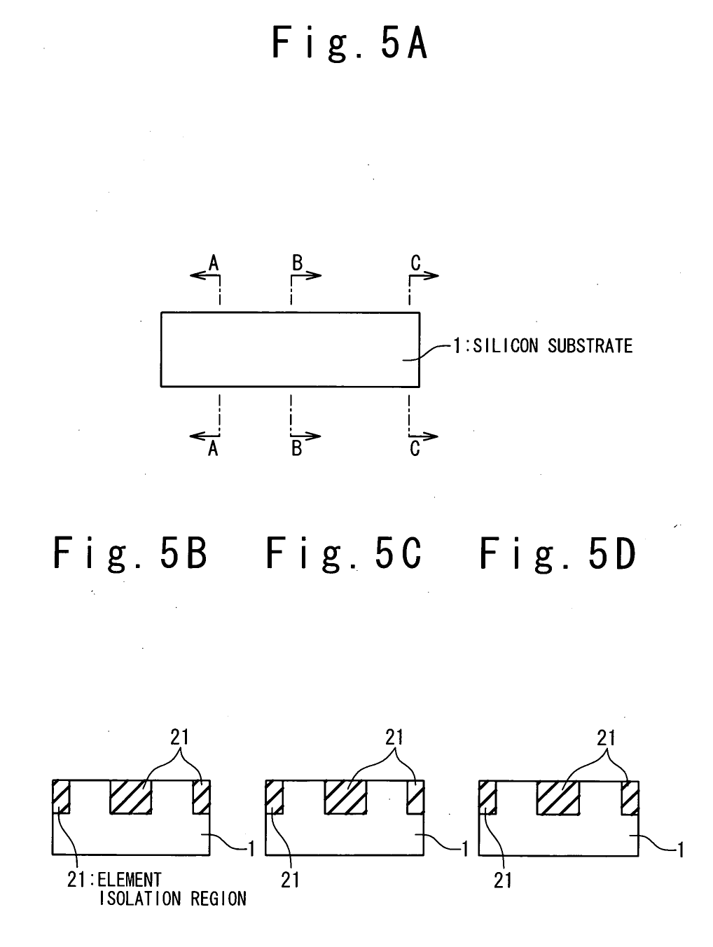

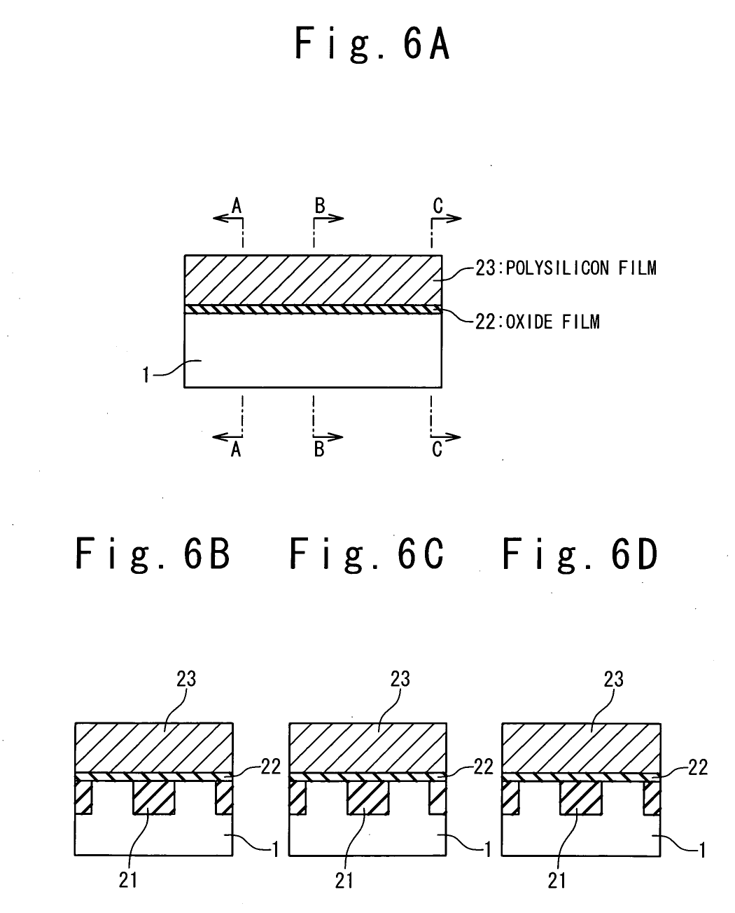

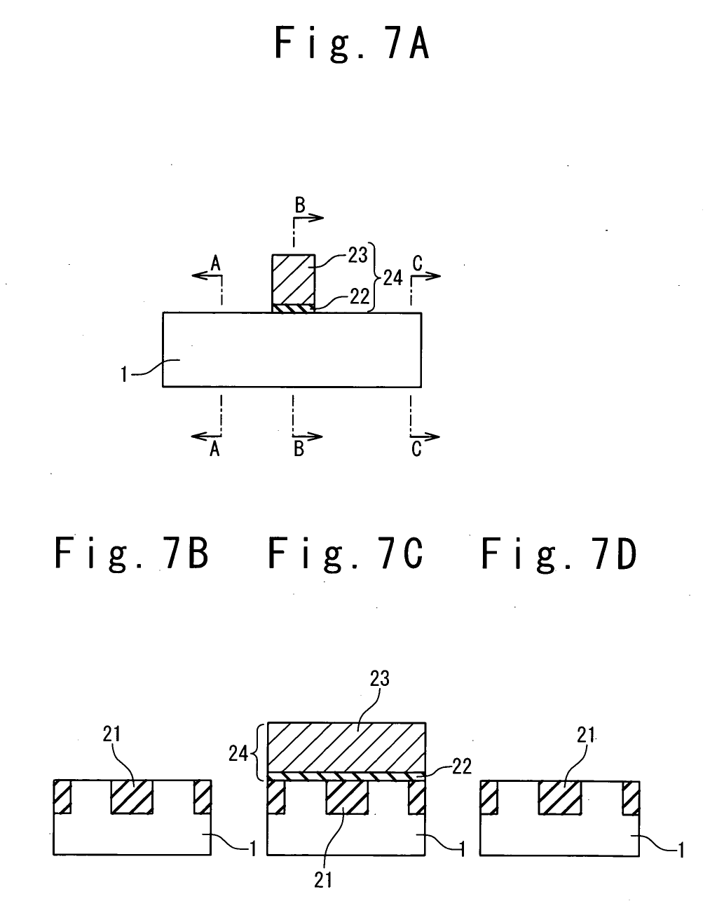

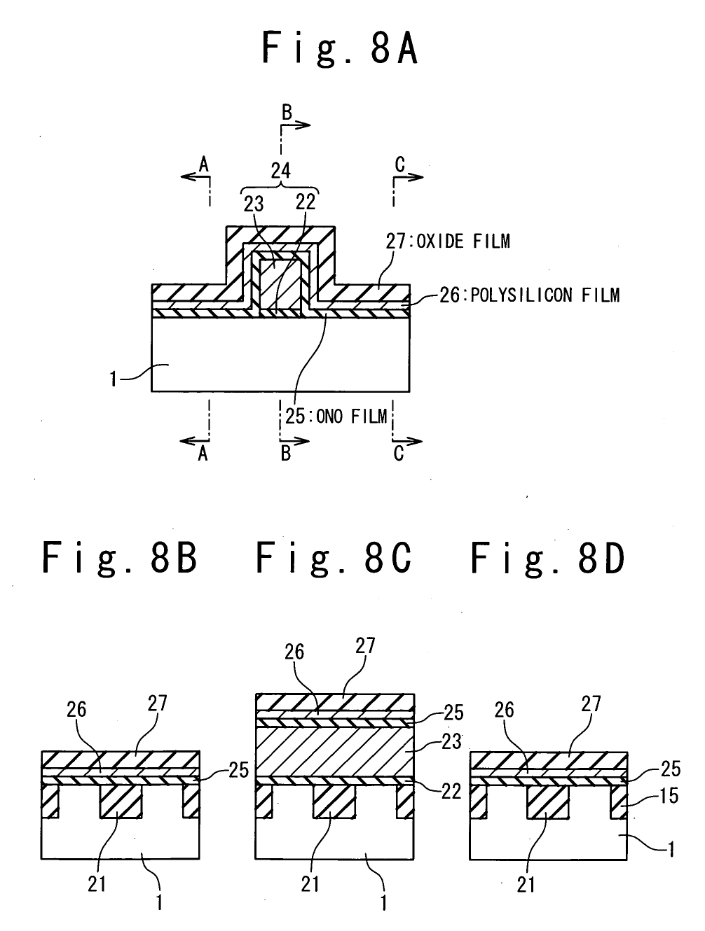

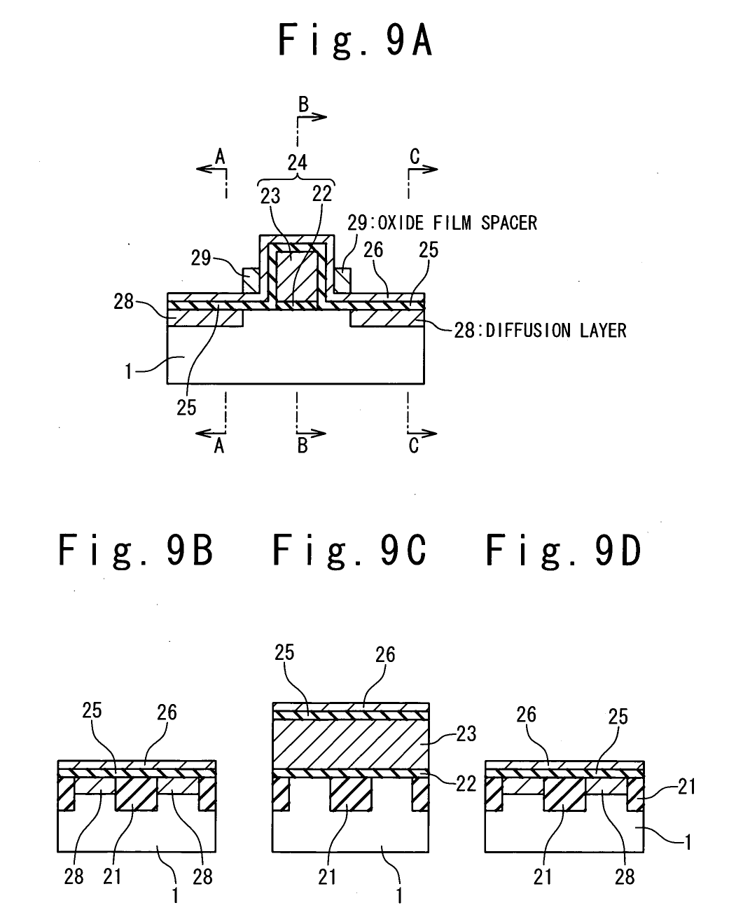

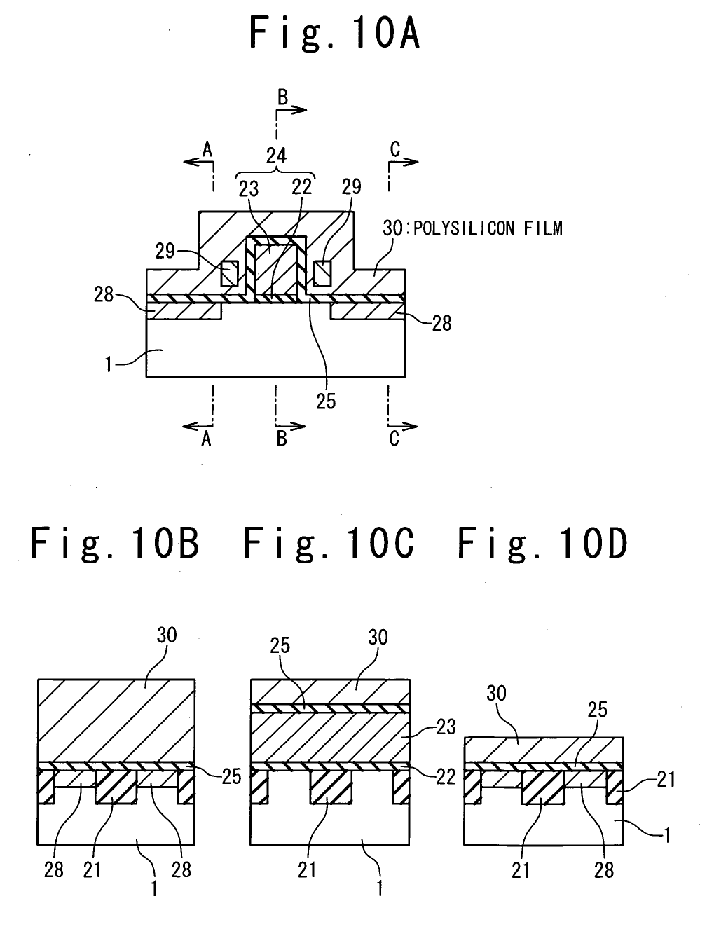

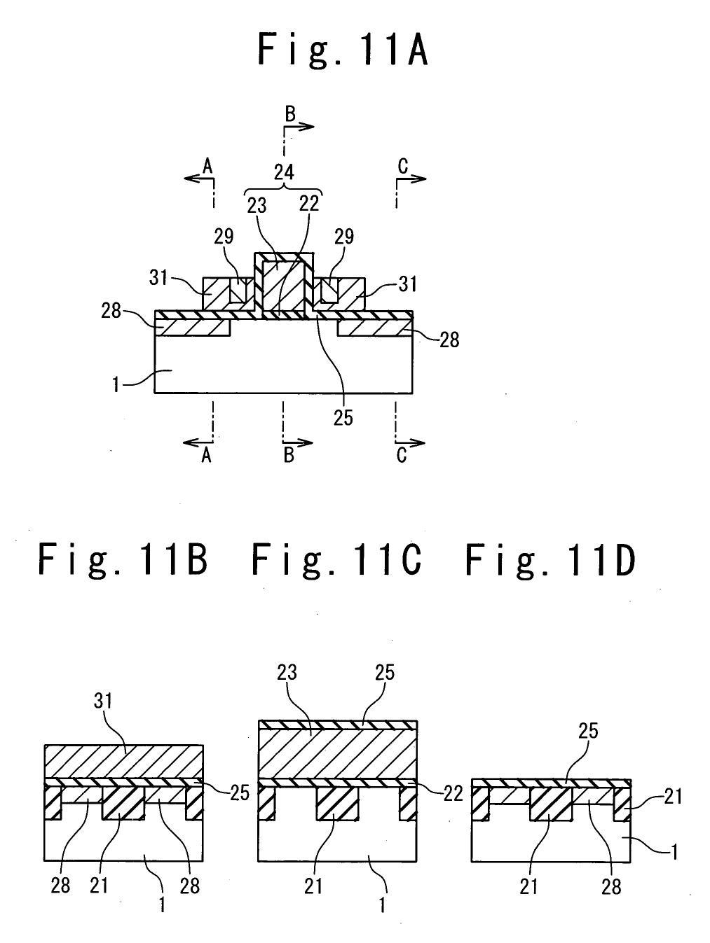

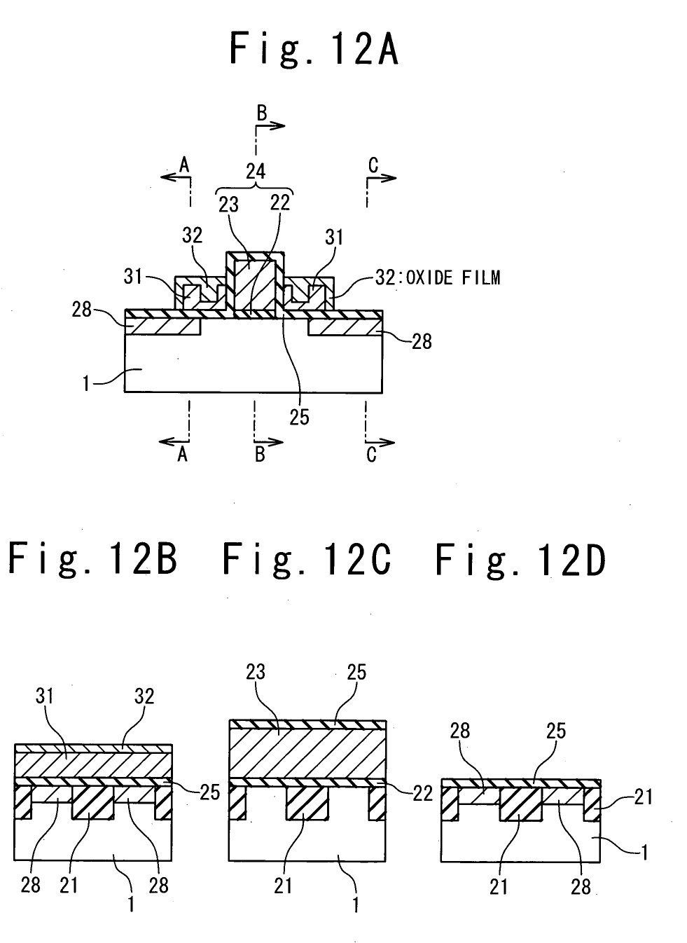

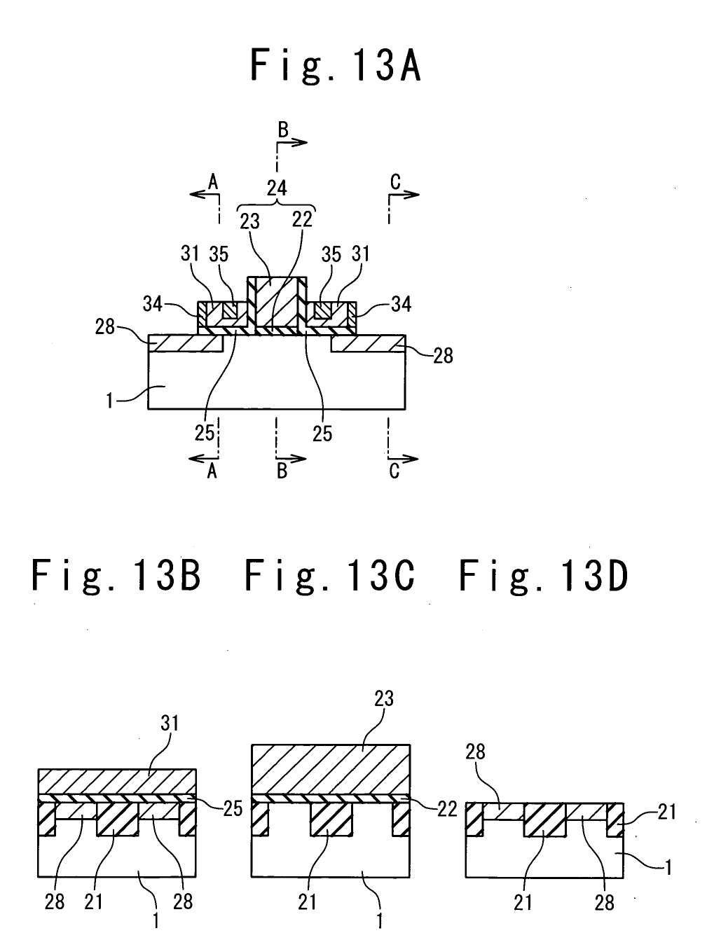

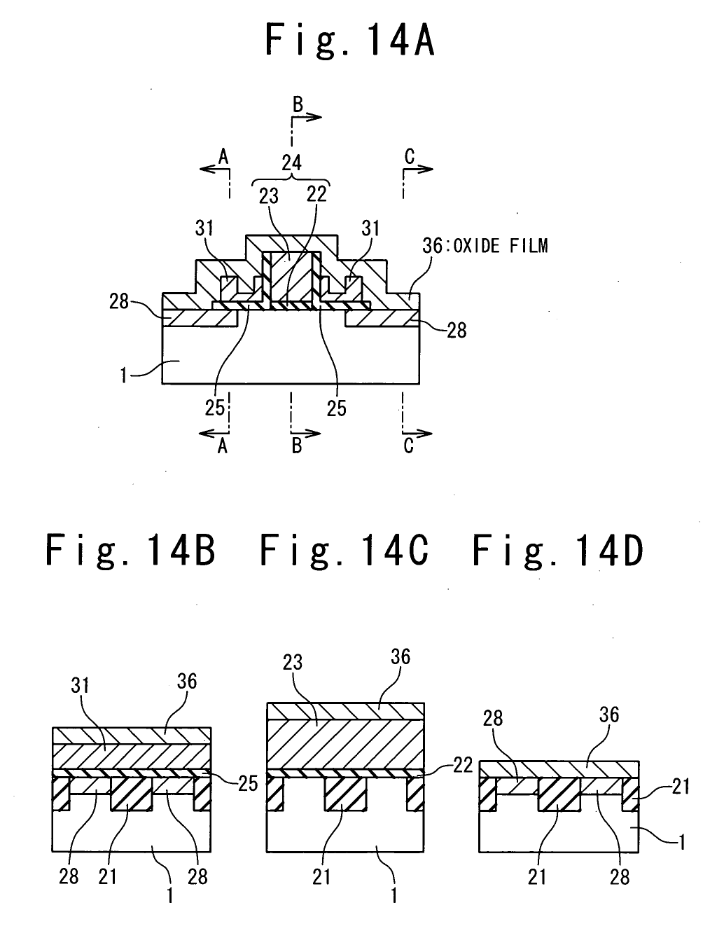

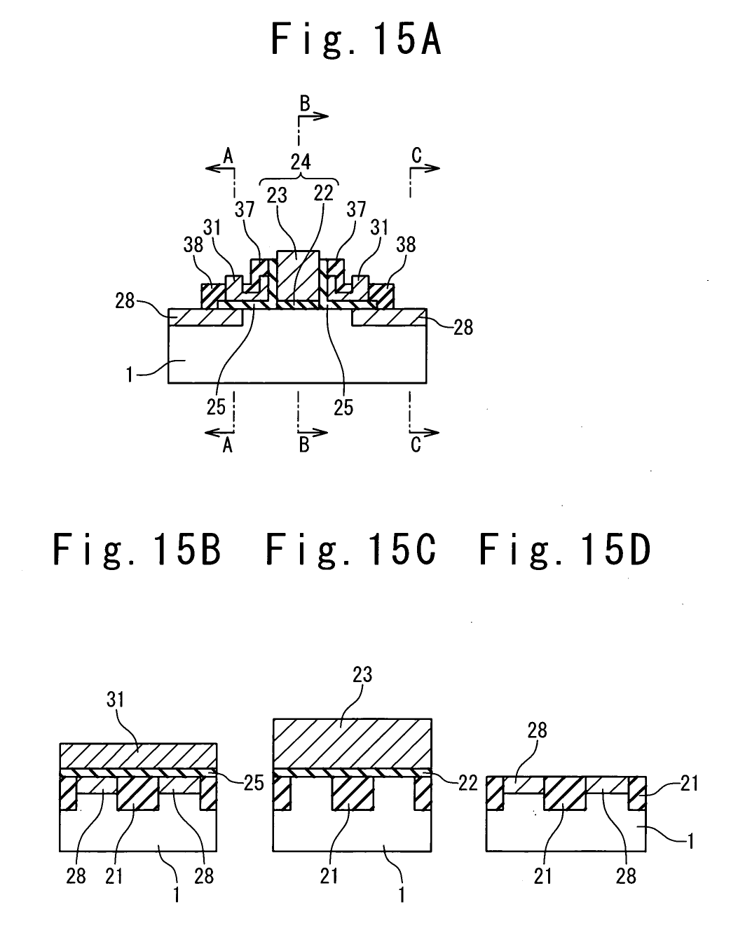

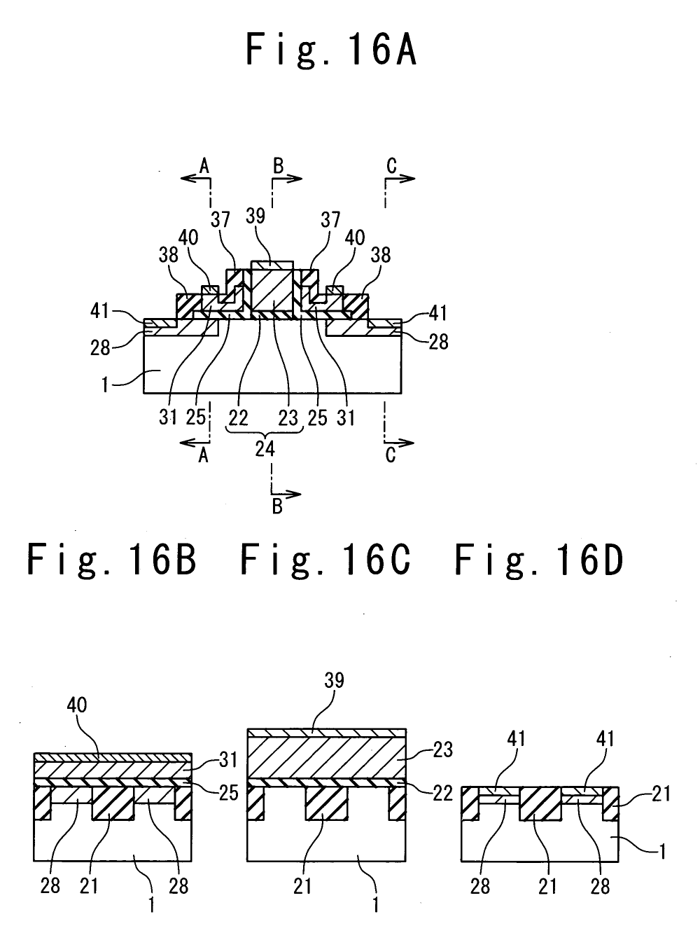

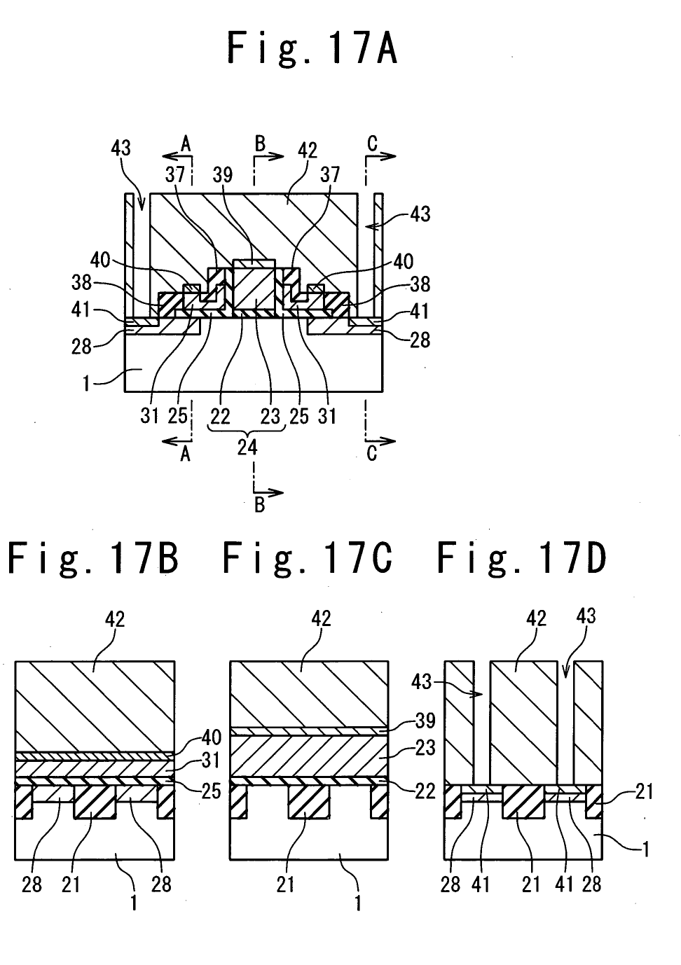

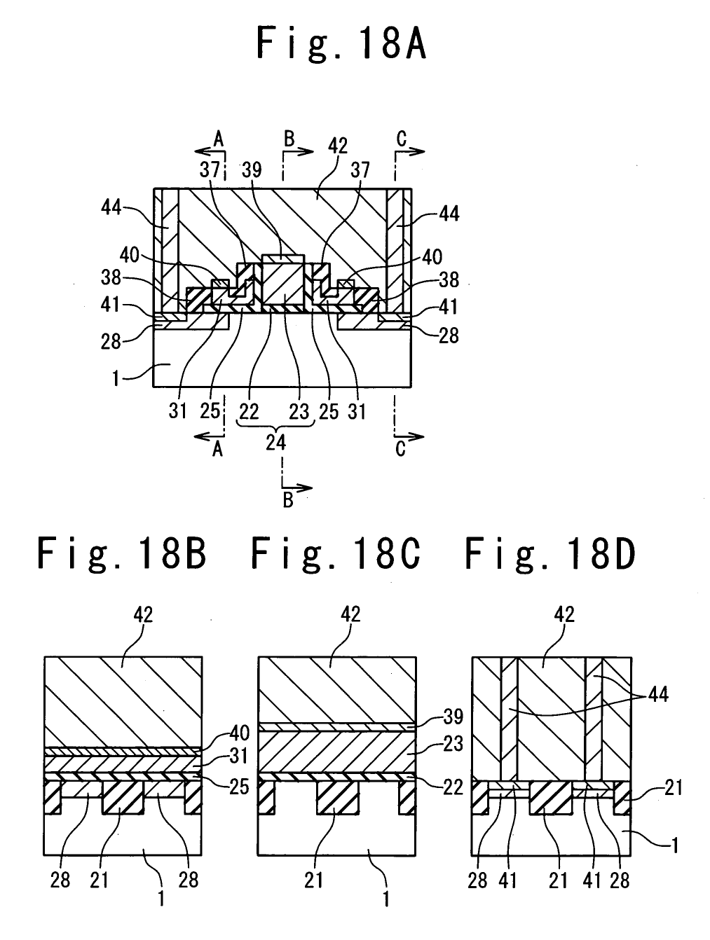

FIGS. 5A to 5D to 18A to 18D are cross-sectional views showing the method for manufacturing the nonvolatile semiconductor memory according to the embodiment of the present invention. In FIGS. 5A to 5D, FIG. 5A is a cross-sectional view in the same direction as that of the cross-sectional view shown in FIG. 3. FIG. 5B is a cross-sectional view taken along a line A-A of FIG. 5A. FIG. 5C is a cross-sectional view taken along a line B-B of FIG. 5A. FIG. 5D is a cross-sectional view taken along a line C-C of FIG. 5A. The relation among FIGS. 6A to 6D to the relation among FIGS. 18A to 18D are the similar to that among FIGS. 5A to 5D.

Referring to FIGS. 5A to 5D, the element isolation region 21 is formed in a predetermined region on the surface of the p-type silicon substrate 1 by a conventional shallow trench isolation (STI) method. Ap well (not shown) deeper than the element isolation region 21 is formed in a predetermined region.

Referring to FIGS. 6A to 6D, an oxide film 22 is formed on the surface of the silicon substrate 1 by the thermal oxidation treatment. A polysilicon film 23 is formed to cover the oxide film 22 by the chemical vapor deposition (CVD) method.

Referring to FIGS. 7A to 7D, the polysilicon film 23 is etched by the photolithography and dry etching while leaving the polysilicon film 23 in a region in which a control gate is formed. Thereafter, while using the polysilicon film 23 as a mask, the oxide film 22 is etched. Thus, a multilayered member 24 containing of the polysilicon film 23 and the oxide film 22 is formed by the etching method.

Referring to FIGS. 8A to 8D, a silicon oxide film, a silicon nitride film, and a silicon oxide film are multilayered to cover the surface of the silicon substrate 1 and the multilayered member 24 by the sputtering method. An ONO film 25 serving as a charge accumulation layer is thereby formed. Thereafter, a polysilicon film 26 is formed to cover the ONO film 25 by the CVD method. A silicon oxide film 27 is formed to cover the polysilicon film 26 by the CVD method.

Referring to FIGS. 9A to 9D, the oxide film 27 is etched back to form an oxide film spacer 29. It is noted that the oxide film spacer 29 is formed on the polysilicon film 26 corresponding to a corner formed by a side surface of the multilayered member 24 and the surface of the silicon substrate 1. Thereafter, while using the multilayered member 24, the polysilicon film 26 and the ONO film 25 that cover the multilayered member 24 and the oxide film spacer 29 as a mask, n type impurities such as arsenic (As) impurities are implanted. By doing so, diffusion layers 28 are formed in a self-aligned manner in a region on the surface of the silicon substrate 1, except for the region right under the multilayered member 24, the polysilicon film 26 and the ONO film 25 that cover the multilayered member 24, and the oxide film spacer 29, and except for the element isolation region 21.

Referring to FIGS. 10A to 10D, a polysilicon film 30 is formed to cover the polysilicon film 26 and the oxide spacer 29 by the CVD method.

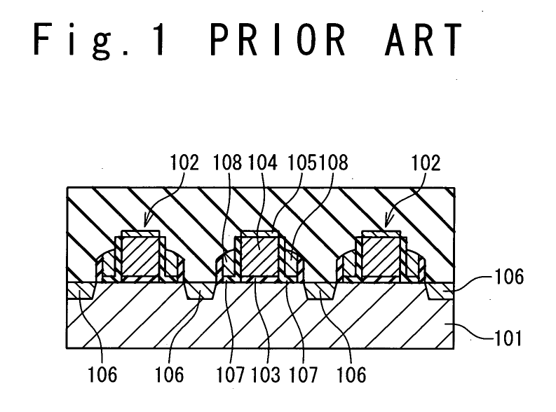

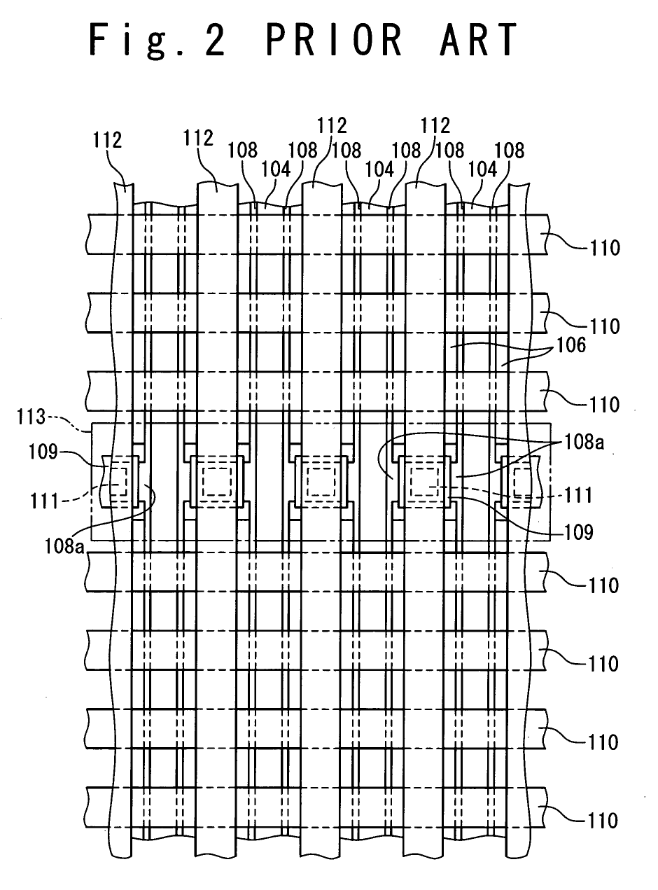

Referring to FIGS. 11A to 1D, the polysilicon film 30 is etched back to thereby expose an upper portion of the ONO film 25 that covers the multilayered member 24, an upper surface of the oxide spacer 29, and the ONO film 25 on the diffusion layers 28. By doing so, the polysilicon film 30 becomes a polysilicon film 31. The polysilicon film 31 is formed to be lower than the multilayered member 24 on the ONO film 25 corresponding to a corner formed by the side surface of the multilayered member 24 and the surface of the silicon substrate 1 so as to surround a lower side and surroundings of the oxide film spacer 29.

Referring to FIGS. 12A to 12D, an oxide film 32 is formed on a surface of the etched back polysilicon film 31 by the thermal oxidation treatment.

Referring to FIGS. 13A to 13D, the ONO film 25 and the oxide film 32 are etched back to thereby expose an upper surface of the multilayered member 24, the surfaces of the polysilicon film 31, and surfaces of the diffusion layers 28 (except for a region below the polysilicon film 31 and the oxide film 32). As a result, the oxide film 32 is separated into an oxide film 34 outside the polysilicon film 31 and an oxide film 35 inside the polysilicon film 31 (at a position where the oxide spacer 29 was present).

Thereafter, a part of steps of forming peripheral circuits (e.g., polysilicon film etching and ion implantation) are executed (not shown).

Referring to FIGS. 14A to 14D, an oxide film is formed to cover the entire surface of the silicon substrate 1 by the CVD method. As a result, an oxide film 36 including the oxide films 34 and 35 is formed to cover the entire surface of the silicon substrate 1.

Referring to FIGS. 15A to 15D, the oxide film 36 and the ONO film 25 are etched back to thereby expose the upper portion of the multilayered member 24, an upper portion of the polysilicon film 31 on a side farther from the multilayered member 24, and a part of the diffusion layers 28 (except for a region below the ONO film 25 and the oxide film 36 near the ONO film 25). As a result, the oxide film 36 is separated into oxide films 37 and 38. The oxide film 37 covers the ONO film 25 on the side surface of the multilayered member 24 and the multilayered member 24-side polysilicon film 31. The oxide film 38 covers a side surface of the diffusion layer 28-side polysilicon film 31, the ONO film 25, and the diffusion layers 28 near the ONO film 25.

Referring to FIGS. 16A to 16D, a cobalt film is formed on the entire surface of the silicon substrate 1 by the sputtering method. Thereafter, a heat treatment is performed. The heat treatment produces a reaction of the upper portion of the multilayered member 24 with the cobalt film, thereby forming a silicide film 39 containing of cobalt silicide on the upper portion of the multilayered member 24. In addition, the upper portion of the polysilicon film 31 on the side farther from the stacked member 24 reacts with the cobalt film, thereby forming a silicide film 40 containing of cobalt silicide on the upper potion of the polysilicon film 31. Further, a part of each diffusion layers 28 (except for the region below the ONO film 25 and the oxide film 38) react with the cobalt film, thereby forming a silicide film 41 containing of cobalt silicide on the part of each diffusion layer 28. Thereafter, the cobalt film other than the silicide films is etched away.

Referring to FIGS. 17A to 17D, an interlayer insulating layer 42 is formed on the entire surface of the silicon substrate 1 by the CVD method. Thereafter, a contact hole 43 is formed by the photolithography method and the dry etching method.

Referring to FIGS. 18A to 18D, a copper film is formed on the entire surface of the silicon substrate 1 by the sputtering method. Thereafter, the copper film on the interlayer insulating film 42 is removed by the chemical mechanical polishing (CMP) method. A contact 44 is formed in the contact hole 42.

Since subsequent processes are well-known processes, they will not be described herein.

The nonvolatile semiconductor memory is manufactured by the above-stated manufacturing method.

That is, above method for manufacturing a nonvolatile semiconductor memory, includes: (a) forming a multilayered insulating film, a second conductive film and a second insulating film in this order to cover surfaces of a multilayered member and a semiconductor substrate, wherein the multilayered member includes a first insulating film and a first conductive film formed on a first region on a semiconductor substrate; (b) etching back the second insulating film to form insulating spacers covering first positions on the second conductive film, each of the first positions corresponds to an intersection between the surfaces of the multilayered member and the semiconductor substrate; (c) forming a diffusion layer on the surface of the semiconductor substrate by self-aligned ion implantation with an area between the insulating spacers as a mask; (d) forming a conductive film to cover the second conductive film and the insulating spacers to be a third conductive film with the second conductive film; (e) etching back the third conductive film such that a upper surface of the insulating spacers and a part of a surface of the multilayered insulating film are exposed and the third conductive film on side surfaces of the insulating spacers remains; (f) forming a third insulating film on the semiconductor substrate; (g) etching back the third insulating film and the multilayered insulating film such that an upper portion of the multilayered member, an upper portion of the third conductive film far from the multilayered member and a part surface of the diffusion layers are exposed; and (h) forming silicide at part surfaces of the upper portion of the multilayered member, the upper portion of the third conductive film far from the multilayered member and the part surface of the diffusion layers.

In the method for manufacturing a nonvolatile semiconductor memory, the step (f) may include: (f1) forming a silicon oxide film by oxidizing surfaces of the multilayered member and the third conductive film, the step (g) may include: (g1) etching back the silicon oxide film in addition to the third insulating film and the multilayered insulating film such that the upper portion of the multilayered member, the upper portion of the third conductive film far from the multilayered member and the part surface of the diffusion layers are exposed.

In the method for manufacturing a nonvolatile semiconductor memory, the step (f) may include: (f1) forming a silicon oxide film by oxidizing surfaces of the multilayered member and the third conductive film, the step (g) may include: (g1) etching back the silicon oxide film and the multilayered insulating film such that parts of the multilayered member and the third conductive film, and (g2) etching back the silicon oxide film in addition to the third insulating film and the multilayered insulating film such that the upper portion of the multilayered member, the upper portion of the third conductive film far from the multilayered member and the part surface of the diffusion layers are exposed.

In the method for manufacturing a nonvolatile semiconductor memory, the step (e) may include: (e1) etching back the third conductive film such that a part of the diffusion layer is covered with a remaining part of the third conductive film.

In the method for manufacturing a nonvolatile semiconductor memory, the step (e) may include: (e1) etching back the third conductive film such that a height of the etched third conductive film from the surface of the semiconductor substrate is shorter than that of the first conductive film from the surface of the semiconductor substrate.

In the method for manufacturing a nonvolatile semiconductor memory, the multilayered insulating film may include a multilayered structure in which a first silicon oxide layer, an insulating film higher in dielectric constant than a silicon oxide and a second silicon oxide film are formed in this order.

In the nonvolatile semiconductor memory, the insulating film may include a silicon nitride.

In the nonvolatile semiconductor memory, the multilayered insulating film may include a structure in which a plurality of conductive particles are dispersed in an insulating film.

It is noted that correspondence between the respective constituent elements shown in FIG. 3 and those shown in FIG. 18 is as follows.

The diffusion layer 3, the gate insulating film 5, the control gate 6, the memory layer 7, the memory gate 8, the silicide 9, the silicide 10, the silicide 11, the contact 12, and the interlayer insulating layer 14 shown in FIG. 3 correspond to the diffusion layer 28, the gate insulating film 22, the control gate 23, the memory layer 25, the memory gate 31, the silicide 39, the silicide 40, the silicide 41, the contact 44, and ((the interlayer insulating layer 42)+(the oxide film 37)+(oxide film 38)) shown in FIG. 18, respectively.

According to the present invention, the nonvolatile semiconductor memory can operate at high rate while suppressing the macro size thereof to be small. It is possible to prevent the electrical connection between the silicide of the memory gate and that of the control gate. The nonvolatile semiconductor memory can be manufactured at high yield.

It is apparent that the present invention is not limited to the above embodiment, that may be modified and changed without departing form the scope and spirit of the invention.

What is claimed is:

1. A nonvolatile semiconductor memory comprising:
a gate insulating layer which is formed on a first region of a semiconductor substrate;
a control gate layer which is formed on said gate insulating layer;
a first silicide layer which is formed on said control gate layer;
charge accumulating layers, each of which is formed on one of both sides of said first region of said semiconductor substrate, and capable to accumulate charges;
memory gate layers, each of which is formed on one of said charge accumulating layers, away from said control gate layer; and
second silicide layers, each of which is formed on one of said memory gate layers,
wherein said one of the memory gate layers includes:
a thick gate layer which is formed far side from said control gate layer, and bonded to one of said second silicide layers, and
a thin gate layer which is formed near side from said control gate layer, thinner in a layer thickness than said thick gate layer and shorter in a height than said control gate layer.

2. The nonvolatile semiconductor memory according to claim 1, wherein said one memory gate layer is one of approximately U-shaped and J-shaped, in which said thick gate layer is a layer corresponding to one longitudinal part of one of said U shape and J shape, and said thin gate layer is a layer corresponding to a bottom of said one of the U shape and J shape.

3. The nonvolatile semiconductor memory according to claim 1, wherein said one memory gate layer includes:
a boundary gate which is formed on nearer side form said control gate layer than said thin gate layer, and taller in a height than said thin gate layer.

4. The nonvolatile semiconductor memory according to claim 1, further comprising:
diffusion layers, each of which is embedded in a region of said semiconductor substrate under said one second silicide layer.

5. The nonvolatile semiconductor memory according to claim 1, wherein a height of said thick gate layer from a surface of said semiconductor substrate is shorter than that of said control gate layer from said surface of the semiconductor substrate.

6. The nonvolatile semiconductor memory according to claim 1, wherein said one of said charge accumulating layers is connected to sides of said gate insulating layer and said control gate layer.

7. The nonvolatile semiconductor memory according to claim 1, wherein said one of said charge accumulating layers includes a multilayered structure in which a first silicon oxide layer, an insulating film higher in dielectric constant than a silicon oxide and a second silicon oxide film are formed in this order.

8. The nonvolatile semiconductor memory according to claim 7, wherein said insulating film includes a silicon nitride.

9. The nonvolatile semiconductor memory according to claim 1, wherein said one of said charge accumulating layers includes a structure in which a plurality of conductive particles are dispersed in an insulating film.

10. A nonvolatile semiconductor memory comprising:
a gate insulating layer which is formed on a first region of a semiconductor substrate;
a control gate layer which is formed on said gate insulating layer;
a first silicide layer which is formed on said control gate layer;
charge accumulating layers, each of which is formed on one of both sides of said first region of said semiconductor substrate, and capable to accumulate charges;
memory gate layers, each of which is formed on one of said charge accumulating layers and has a concave portion; and
second silicide layers, each of which is formed on a convex portion of one of said memory gate layers.

11. The nonvolatile semiconductor memory according to claim 10, wherein said convex portion is formed farther from control gate layer than said concave portion.

12. The nonvolatile semiconductor memory according to claim 10, wherein said one of the memory gate layers is one of approximately U-shaped and J-shaped.

13. The nonvolatile semiconductor memory according to claim 10, wherein a height of said one of the memory gate layers from a surface of said semiconductor substrate is shorter than that of said control gate layer from said surface of the semiconductor substrate.

14. The nonvolatile semiconductor memory according to claim 10, wherein said one of said charge accumulating layers includes a multilayered structure in which a first silicon oxide layer, an insulating film higher in dielectric constant than a silicon oxide and a second silicon oxide film are formed in this order.

15. The nonvolatile semiconductor memory according to claim 14, wherein said insulating film includes a silicon nitride.

16. The nonvolatile semiconductor memory according to claim 10, wherein said one of said charge accumulating layers includes a structure in which a plurality of conductive particles are dispersed in an insulating film.
